(19) United States
(12) Patent Application Publication
(10) Pub. No.: US 2026/0066914 A1
(43) Pub. Date: Mar. 5, 2026

(54) HYBRID OVERSAMPLED ANALOG TO DIGITAL CONVERTER

(71) Applicant: TEXAS INSTRUMENTS INCORPORATED, Dallas, TX (US)

(72) Inventors: Nanqi LIU, Tucson, AZ (US); Amit GUPTA, Frisco, TX (US); Dhyey Naren DESAI, Tucson, AZ (US)

(21) Appl. No.: 18/817,759

(22) Filed: Aug. 28, 2024

(51) Int. Cl. H03M 1/10

(52) U.S. Cl. CPC H03M 1/1014

(57) ABSTRACT

A circuit includes a switched capacitor amplifier circuit, a multi-bit quantizer circuit, an accumulator circuit, a cyclic result register, and a result combination circuit. The switched capacitor amplifier circuit has an output. The multi-bit quantizer circuit has an input coupled to the output of the switched capacitor amplifier circuit, and an output. The accumulator circuit has an input coupled to the output of the multi-bit quantizer circuit, and an output. The cyclic result register has an input couped to the output of the multi-bit quantizer, and an output. The result combination circuit has a first input coupled to the output of the accumulator circuit, and a second input coupled to the output of the cyclic result register.

### BACKGROUND

Various analog-to-digital data converters and conversion techniques have been developed for converting electrical signals from an analog domain to a digital domain. In general, the process of analog-to-digital conversion includes sampling an analog signal and comparing the sampled analog signal to a threshold value. A binary result is recorded depending upon the result of the comparison. The process of comparing the sample against a threshold may be repeated a number of times with each successive comparison using a different threshold and residue of the sample. The number of iterations typically affects the noise level of any result as well as the resolution of the ultimate digital signal.

### SUMMARY

In one example, a circuit includes a switched capacitor amplifier circuit, a multi-bit quantizer circuit, an accumulator circuit, a cyclic result register, and a result combination circuit. The switched capacitor amplifier circuit has an output. The multi-bit quantizer circuit has an input coupled to the output of the switched capacitor amplifier circuit, and an output. The accumulator circuit has an input coupled to the output of the multi-bit quantizer circuit, and an output. The cyclic result register has an input coupled to the output of the multi-bit quantizer, and an output. The result combination circuit has a first input coupled to the output of the accumulator circuit, and a second input coupled to the output of the cyclic result register.

In another example, an analog-to-digital converter (ADC) circuit includes a switched capacitor amplifier, a capacitive digital-to-analog converter (CDAC), a multi-bit quantizer circuit, an accumulator circuit, a cyclic result register, a calibration circuit, and a result combination circuit. The switched capacitor amplifier has a first input, a second input, and an output. The capacitive CDAC has a first output coupled to the first input of the switched capacitor amplifier, a second output coupled to the second input of the switched capacitor amplifier, and an output. The multi-bit quantizer circuit has an input coupled to the output of the switched capacitor amplifier, and an output coupled to the input of the CDAC. The accumulator circuit has an input coupled to the output of the multi-bit quantizer circuit, and an output. The cyclic result register has an input couped to the output of the multi-bit quantizer circuit, and an output. The calibration circuit has an input coupled to the output of the cyclic result register, and an output. The result combination circuit has a first input coupled to the output of the accumulator circuit, and a second input coupled to the output of the calibration circuit.

In a further example, a circuit includes a switched capacitor amplifier circuit, a multi-bit quantizer circuit, an accumulator circuit, a cyclic result register, and a result combination circuit. The switched capacitor amplifier circuit is configured for delta-sigma analog-to-digital conversion and cyclic analog-to-digital conversion. The multi-bit quantizer circuit is coupled to the switched capacitor amplifier circuit. The multi-bit quantizer circuit is configured to quantize an output signal of the switch capacitor amplifier circuit to multiple bits. The accumulator circuit is coupled to the multi-bit quantizer circuit. The accumulator circuit is configured to accumulate the multiple bits into a delta-sigma analog-to-digital conversion result. The cyclic result register is coupled to the multi-bit quantizer circuit. The cyclic result register is configured to store the multiple bits in a cyclic analog-to-digital conversion result. The result combination circuit is coupled to the accumulator circuit and the cyclic result register. The result combination circuit is configured to combine the delta-sigma analog-to-digital conversion result and the cyclic analog-to-digital conversion result to generate a hybrid analog-to-digital conversion result.

### BRIEF DESCRIPTION OF THE DRAWINGS

FIG. 1 is a schematic diagram of an example hybrid analog-to-digital converter (ADC) that includes multi-bit quantization, double sampling, and digital calibration.

FIG. 2 is schematic diagram of an example multi-bit quantizer circuit suitable for use in the hybrid ADC of FIG. 1.

FIGS. 3A, 3B, 4A, 4B, 5A, 5B, 6A, 6B, 7A, and 7B are schematic diagrams of a capacitive digital-to-analog converter suitable for use in the hybrid ADC of FIG. 1 showing switch settings selected based on multi-bit quantizer circuit output.

FIGS. 8A and 8B are timing diagrams showing example timing of delta-sigma and cyclic conversions in the hybrid ADC of FIG. 1.

FIG. 9 is a flow diagram for an example method for analog-to-digital conversion using a hybrid ADC.

### DETAILED DESCRIPTION

A hybrid analog-to-digital converter (ADC) may apply delta-sigma conversion to generate some bits (e.g., the most significant bits) of a conversion, and apply another conversion technique (e.g., cyclic conversion) to digitize a residue of the delta-sigma conversion and generate other bits (e.g., the least significant bits) of the conversion. The results of the two conversions are combined to produce a hybrid converter result value. By using the two conversion techniques, the hybrid converter can reduce conversion time, relative to a delta-sigma converter, while providing high resolution and reasonable noise performance. However, hybrid ADCs are not without shortcomings. For example, the delta-sigma conversion may need a large oversampling ratio to provide high resolution, which increases conversion time. Furthermore, using cyclic conversion to digitize the residue of the delta-sigma conversion can introduce differential non-linearity (DNL) due to mismatch of the capacitors in the hybrid converter. DNL can be reduced by increasing the size of the capacitors used in the converter, which increases circuit area and cost.

The hybrid converters described herein include a multi-bit quantizer applied in both delta-sigma and cyclic conversion. Use of multi-bit quantization reduces the conversion time of both delta-sigma and cyclic conversion. The hybrid converters described herein may also include a calibration circuit that adjusts the results of cyclic conversion to reduce DNL.

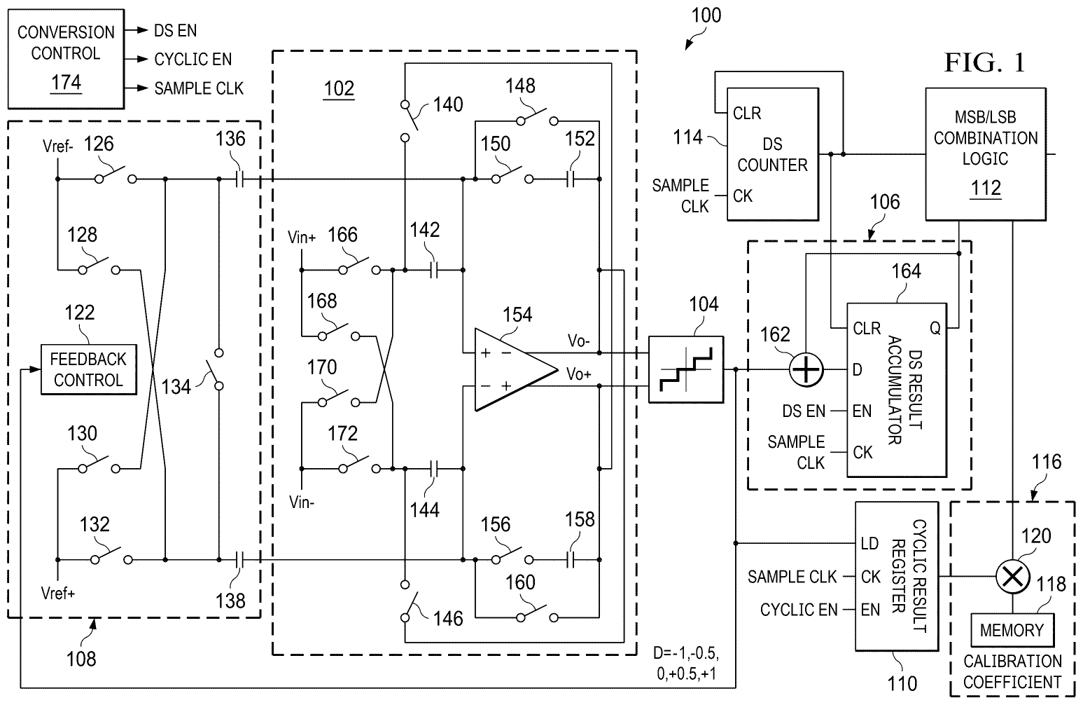

FIG. 1 is a schematic diagram of an example hybrid ADC 100 that includes multi-bit quantization. The hybrid ADC 100 includes a switched capacitor amplifier circuit 102, a multi-bit quantizer circuit 104, an accumulator circuit 106, a capacitive digital-to-analog converter (CDAC) 108, a cyclic result register 110, a result combination circuit 112, and a delta-sigma cycle counter 114. The switched capacitor amplifier circuit 102 samples an input signal to be digitized and is configurable for use in delta-sigma and cyclic conversion. The switched capacitor amplifier circuit 102 has signal inputs Vin+ and Vin−, feedback inputs, and outputs. The switched capacitor amplifier circuit 102 includes an amplifier 154, switches 140, 146, 148, 150, 156, 160, 166, 168, 170, and 172, and capacitors 142, 144, 152, and 158. The capacitors 142 and 144 are sample capacitors. The capacitors 152 and 158 are feedback capacitors.

The amplifier 154 may be a fully differential amplifier having first and second inputs and first and second outputs. The switch 166 and the capacitor 142 are coupled in series between the first input (e.g., non-inverting input) of the amplifier 154 and Vin+. A first terminal of the switch 166 is coupled to Vin+, and a second terminal of the switch 166 is coupled to a first terminal of the capacitor 142. A second terminal of the capacitor 142 is coupled to the first input of the amplifier 154. The switch 172 and the capacitor 144 are coupled in series between the second input (e.g., inverting input) of the amplifier 154 and Vin−. A first terminal of the switch 172 is coupled to Vin−, and a second terminal of the switch 172 is coupled to a first terminal of the capacitor 144. A second terminal of the capacitor 144 is coupled to the second input of the amplifier 154. The switch 168 is coupled between Vin+ and the first terminal of the capacitor 144. The switch 170 is coupled between Vin− and the first terminal of the capacitor 142. Switches 166, 168, 170, 172 may be used for double sampling the input voltage in some examples of the hybrid ADC 100.

The switch 148 is coupled between the first output of the amplifier 154 and the first input of the amplifier 154. The switch 150 and the capacitor 152 are coupled in series between the first output of the amplifier 154 and the first input of the amplifier 154. The switch 160 is coupled between the second output of the amplifier 154 and the second input of the amplifier 154. The switch 156 and the capacitor 158 are coupled in series between the second output of the amplifier 154 and the second input of the amplifier 154. The switch 146 is coupled between the first output of the amplifier 154 and the first terminal of the capacitor 144. The switch 140 is coupled between the second output of the amplifier 154 and the first terminal of the capacitor 142.

The multi-bit quantizer circuit 104 has inputs coupled to the outputs of the switched capacitor amplifier circuit 102 (the outputs of the amplifier 154). The multi-bit quantizer circuit 104 receives the switched capacitor amplifier output signal provided at the outputs switched capacitor amplifier circuit 102, and compares the signal to multiple reference voltages to produce a multi-bit output. Examples of the multi-bit quantizer circuit 104 may include multiple comparators that compare the signal received from the switched capacitor amplifier circuit 102 to multiple reference voltages to produce multiple output bits that represent the received signal. In FIG. 1, the multi-bit value (D) provided by the multi-bit quantizer circuit 104 may have values of −1, −0.5, 0, +0.5, and +1 corresponding to a 2.5-bit quantizer output. Some examples of the multi-bit quantizer circuit 104 may provide different values of D. The multi-bit output of the multi-bit quantizer circuit 104 is coupled to multi-bit inputs of the accumulator circuit 106, the CDAC 108, and the cyclic result register 110.

The CDAC 108 includes capacitors 136 and 138, switches 126, 128, 130, 132, and 134, and a feedback control circuit 122. An input of the feedback control circuit 122 is coupled to the output of the multi-bit quantizer circuit 104 for receipt of the multi-bit value provided by the multi-bit quantizer circuit 104. Outputs of the feedback control circuit 122 are coupled to control inputs of the switches 126, 128, 130, 132, and 134. The feedback control circuit 122 controls the switches of the CDAC 108 to generate a voltage representative of the multi-bit value received from the multi-bit quantizer circuit 104 by switching the reference voltages provided at the reference terminals Vref+ and Vref− to the capacitors 136 and 138 in multiple phases. The switch 126 has a first terminal coupled to Vref−, and a second terminal coupled to the first terminal of the capacitor 136. A second terminal of the capacitor 136 serves as an output of the CDAC 108, and is coupled to the first input of the amplifier 154. The switch 132 has a first terminal coupled to Vref+, and a second terminal coupled to the first terminal of the capacitor 138. A second terminal of the capacitor 138 serves as an output of the CDAC 108, and is coupled to the second input of the amplifier 154. The switch 128 is coupled between the first terminal of the switch 126 and the second terminal of the switch 132. The switch 130 is coupled between the first terminal of the switch 132 and the second terminal of the switch 126. The switch 134 is coupled between the second terminal of the switch 126 and the second terminal of the switch 132.

The CDAC 108 applies the multi-bit value D using a two phase operation (double sampling mode) to generate a feedback voltage representative of the multi-bit value D. The feedback control circuit 122 controls the switches 126, 128, 130, 132, and 134 in two phases to control generation of the feedback voltage provided at the outputs of the CDAC 108 (to the switched capacitor amplifier circuit 102). Use of double sampling allows the CDAC 108 to generate output voltages corresponding to D without increasing the number of capacitors in the CDAC 108 (and increasing the likelihood of mismatch). The CDAC 108 may generate feedback signals using a double sample mode responsive to some values of D, using a single sampling mode responsive to other values of D.

The accumulator circuit 106 includes an accumulator register 164 and a multi-bit adder 162. The multi-bit adder 162 has a first input coupled to the output of the multi-bit quantizer circuit 104, a second input coupled to an output of the accumulator register 164, and an output coupled to an input of the accumulator register 164. During delta-sigma conversion, the accumulator circuit 106 receives D provided by the multi-bit quantizer circuit 104 and sums D with the accumulated value stored in the accumulator register 164. The accumulator circuit 106 has an enable input (EN) and a clock input coupled to the conversion control circuit 174. A delta-sigma conversion result is provided at the output of the accumulator register 164.

The conversion control circuit 174 generates the signals that configure the hybrid ADC 100 for delta-sigma and cyclic conversion. The conversion control circuit 174 generates a SAMPLE CLK signal that defines a conversion cycle, a DS EN signal that is logic high during a delta-sigma conversion, and a CYCLIC EN signal that is a logic high during a cyclic conversion. The conversion control circuit 174 may also generate switch control signals that control the switches of the switched capacitor amplifier circuit 102.

The delta-sigma cycle counter 114 counts cycles of the SAMPLE CLK received from the conversion control circuit 174 to set the number of delta-sigma conversion cycles in a delta-sigma conversion. A clock input of the delta-sigma cycle counter 114 is coupled to an output of the conversion control circuit 174 for receipt of SAMPLE CLK.

The cyclic result register 110 has a data input coupled to the output of the multi-bit quantizer circuit 104 for receipt of D, an enable input coupled to an output of the conversion control circuit 174, and a clock input coupled to an output of the conversion control circuit 174. The cyclic result register 110 receives and stores D as part of a cyclic conversion result. A cyclic conversion result is provided at the output of the cyclic result register 110.

The result combination circuit 112 has an input coupled to the output of the accumulator register 164, an input coupled to the output of the cyclic result register 110, and an input coupled to the output of the delta-sigma cycle counter 114. The signal provided at the output of the delta-sigma cycle counter 114 specifies a time at which delta-sigma conversion is complete, and the delta-sigma conversion result is ready. The result combination circuit 112 receives the delta-sigma conversion result from the accumulator circuit 106 and the cyclic conversion result from the cyclic result register 110, and combines the delta-sigma conversion result and the cyclic conversion result to generate an ADC conversion result. The result combination circuit 112 includes circuitry that can combine the delta-sigma conversion result with the cyclic conversion result to provide an ADC result. In some examples, the result combination circuit 112 may append the delta-sigma conversion result to the cyclic conversion result with the delta-sigma conversion result constituting the most significant bits of the ADC result, and the cyclic conversion result constituting the least significant bits of the ADC result. In other examples, the result combination circuit 112 includes shift and add circuitry that aligns the least significant bits of the delta-sigma conversion result with the most significant bits of the cyclic conversion result, and adds the delta-sigma conversion result to the cyclic conversion result.

Some examples of the hybrid ADC 100 also include a calibration circuit 116. The calibration circuit 116 includes a coefficient memory 118 and a multiplier 120. The calibration circuit 116 may retrieve a coefficient value from the coefficient memory 118 based on the cyclic conversion result received from the cyclic result register 110, and the multiplier 120 may multiply the cyclic conversion result by the calibration coefficient to generate a calibrated cyclic conversion result. The calibration provided by the calibration circuit 116 may reduce DNL caused by mismatch of capacitors in the hybrid ADC 100 and other errors produced during cyclic conversion.

In operation, the hybrid ADC 100 performs a delta-sigma conversion of a sampled signal to generate more significant bits, and performs cyclic conversion of the delta-sigma residue to generate less significant bits. For delta-sigma conversion, the DS EN signal is active (e.g., a logic one), the CYCLIC EN signal in inactive (e.g., a logic zero), and switches 140 and 146 remain open. In a sample phase, the switches 146, 150, 156, 168, 170 are open, and the switches 148, 160, 166, 172 are closed. In a first phase (the sample phase), charge from Vin+ and Vin− is stored on the capacitors 142 and 144. In a second phase, the switches 148, 160, 166 and 172 are open, the switches 150, 156, 168 and 170 are closed, and charge is transferred from the capacitors 142 and 144 to the capacitors 152 and 158.

In the end of second phase, the multi-bit quantizer circuit 104 quantizes the output signals of the switched capacitor amplifier circuit 102 to generate D, and the accumulator circuit 106 adds the value of D to the value accumulated in the accumulator register 164. D is provided to the CDAC 108, and the feedback control circuit 122 sets the switches of the CDAC 108, based on the value of D, to sample the reference voltage provided at the terminals Vref+ and Vref−. The sampled reference voltage is summed with the signal sampled from Vin+ and Vin− at the inputs of the amplifier 154. The hybrid ADC 100 may execute any number of delta-sigma conversion cycles to produce a delta-sigma conversion result, where resolution of the delta-sigma conversion result increases with the number of cycles. The multi-bit quantizer circuit 104, with the accumulator circuit 106 and CDAC 108, enable the hybrid ADC 100 to reduce the number of cycles needed to produce a desired resolution, which reduces the time needed to produce a result with the desired resolution.

For cyclic conversion, the CYCLIC EN signal is active, the DS EN signal in inactive, the switches 166, 168, 170, and 172 are open, and the switches 140 and 146 are closed. The residue from delta-sigma conversion is provided on the capacitors 152 and 158, and voltage from Vin+ and Vin− is not sampled. The switches 148 and 160 are closed, which causes the capacitors 142 and 144 to discharge. The charge originally maintained on capacitors 152 and 158 is redistributed as differential operational amplifier 154 tries to drive the difference between positive input of differential operational amplifier and negative input to zero. The values of the capacitors 142, 144, 152, and 158 may be selected to provide a desired gain value. For example, the capacitance of the capacitors 152 and 158 may be 4/3 times the capacitance of the capacitors 142 and 144 to provide a gain of four in the switched capacitor amplifier circuit 102 to match the 2.5-bit quantizer circuit so that 2 bits are solved in each cyclic cycle and there is still redundancy for gain error, comparator offset and so on. The gain applied to residue in cyclic conversion may be calculated as:

$$Residue gain = {C}_{152 / 158} / ( {C}_{152 / 158} - {C}_{142 / 144} )$$

where:
C_{152/158} is the capacitance of the capacitor 152 or the capacitor 158; and
C_{142/144} is the capacitance of the capacitor 142 or the capacitor 148.

In some examples of the hybrid ADC 100, the capacitors 142 and 144 may be built using multiple unit capacitors, which allows the capacitance of the capacitors 142 and 144 to be different in delta-sigma mode and cyclic mode. For example, the capacitors 142 and 144 may each be built with 6 unit capacitors. In delta-sigma mode, only one or two or four unit capacitors (which provides different ADC input gain) may be used for sampling every clock cycle and units may be rotated across clock cycles. In cyclic mode, all 6 unit capacitors may be used to provide residue gain=4 if capacitors 152 and 158 are built using 8 unit capacitors.

The multi-bit quantizer circuit 104 quantizes the output signals of the switched capacitor amplifier circuit 102 to generate D, and the cyclic result register 110 stores bit values of D (or derived from D) in bit positions corresponding to the sample period in which D is generated. The CDAC 108 also receives D, and the feedback control circuit 122 sets the switches of the CDAC 108, based on the value of D, to sample the reference voltage provided at the terminals Vref+ and Vref−, and provide feedback to the switched capacitor amplifier circuit 102. The hybrid ADC 100 may execute a number of conversion cycles during cyclic conversion of the delta-signa residue to generate a selected number of bits. In some examples of the hybrid ADC 100, cycle time (e.g., the period of the SAMPLE CLK) may be longer (e.g., twice as long) during cyclic conversion than in delta-sigma conversion.

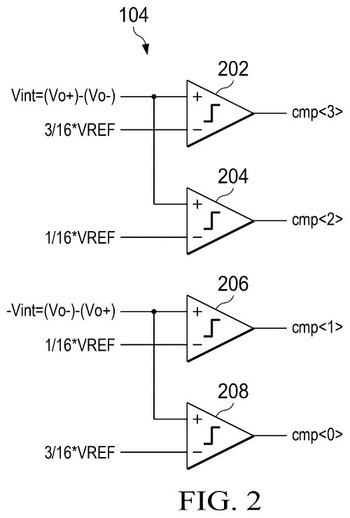

FIG. 2 is schematic diagram of an example of the multi-bit quantizer circuit 104. The multi-bit quantizer circuit 104 includes comparators 202, 204, 206, and 208. The comparator 202 has a first input that is coupled to a Vint terminal having a voltage derived from the output signals of the amplifier 154 ((Vo+)−(Vo−)). A second input of the comparator 202 is coupled to a voltage reference terminal having voltage that is derived from (e.g., 3/16) a voltage VREF. VREF is the voltage at the Vref+ terminal less the voltage at the Vref− terminal. The comparator 204 has a first input coupled to the first input of the comparator 202, and a second input coupled to a voltage reference terminal having voltage that derived from (e.g., 1/16) of the voltage VREF.

The comparator 206 has a first input that is coupled to a −Vint terminal having a voltage derived from the output signals of the amplifier 154 ((Vo−)−(Vo+)). A second input of the comparator 206 is coupled to the second input of the comparator 204. The comparator 208 has a first input coupled to the first input of the comparator 206, and a second input coupled to the second input of the comparator 202. The respective output signals of the comparators 202, 204, 206, and 208 are labeled cmp<3>, cmp<2>, cmp<1>, and cmp<0> respectively. Table 1 shows values of D corresponding to cmp<3>, cmp<2>, cmp<1>, and cmp<0> and Vint voltages. In Table 1, Vref is scaled by a multiple of K, where K may be determined based on the input signal range, power supply voltage, and Vref. K may be 1/16 or other value in some examples. Some examples of the multi-bit quantizer circuit 104 may use a different number of comparators, different thresholds, and or different decoding than is shown in FIG. 2 and Table 1.

TABLE 1

| Vint | cmp<3> | cmp<2> | cmp<1> | cmp<0> | D |
|---|---|---|---|---|---|
| Vint > 3K*Vref | 1 | 1 | 0 | 0 | 1 |
| K*Vref < Vint < 3K*Vref | 0 | 1 | 0 | 0 | 0.5 |
| −K*Vref < Vint < K*Vref | 0 | 0 | 0 | 0 | 0 |
| −3K*Vref < Vint <− KVref | 0 | 0 | 1 | 0 | −0.5 |
| Vint <− 3K*Vref | 0 | 0 | 1 | 1 | −1 |

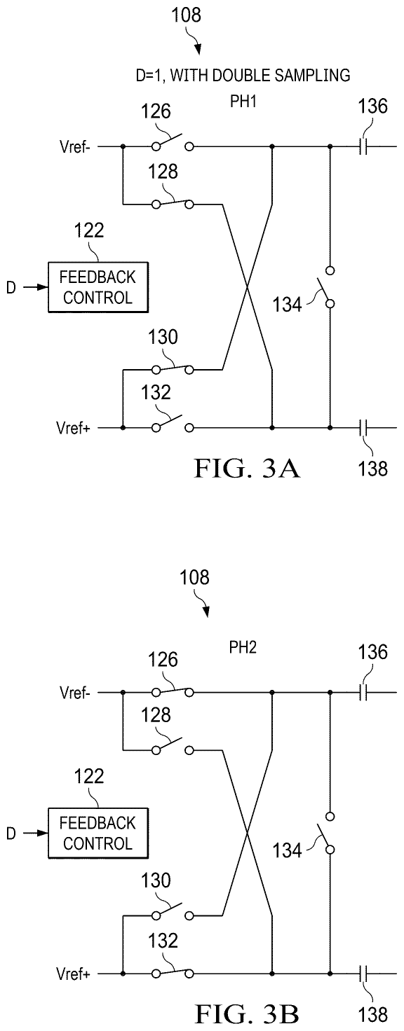

FIGS. 3A, 3B, 4A, 4B, 5A, 5B, 6A, 6B, 7A, and 7B are schematic diagrams of the CDAC 108 showing switch settings selected based on D. FIGS. 3A and 3B show the CDAC 108 set for phases 1 and 2 respectively with D=1. In FIG. 3A (phase 1), the feedback control circuit 122 opens the switches 126, 132, and 134, and closes the switches 128 and 130. Vref is coupled to the first terminal of the capacitor 136, and Vref− is coupled to the first terminal of the capacitor 138. In FIG. 3B (phase 2), the feedback control circuit 122 opens the switches 128, 130, and 134, and closes the switches 126 and 132. Vref+ is coupled to the first terminal of the capacitor 138, and Vref− is coupled to the first terminal of the capacitor 136. The operations of FIGS. 3A and 3B perform a double sampling of reference voltage and feedback Vref− to the switched capacitor amplifier circuit 102.

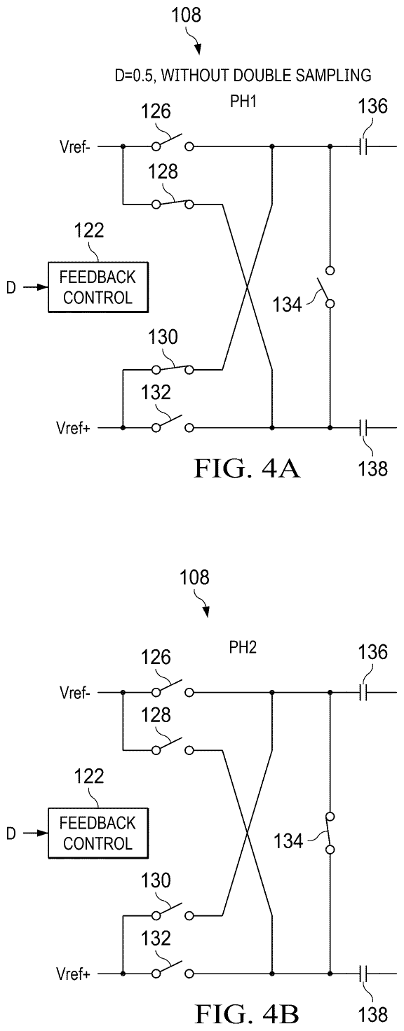

FIGS. 4A and 4B show the CDAC 108 set for phases 1 and 2 respectively with D=0.5. In FIG. 4A (phase 1), the feedback control circuit 122 opens the switches 126, 132, and 134, and closes the switches 128 and 130. Vref+ is coupled to the first terminal of the capacitor 136, and Vref− is coupled to the first terminal of the capacitor 138. In FIG. 4B (phase 2), the feedback control circuit 122 opens the switches 126, 128, 130, and 132, and closes the switch 134. The first terminal of the capacitor 136 is coupled to the first terminal of the capacitor 138 via the switch 134. The operations of FIGS. 4A and 4B perform a single sampling of reference voltage and feedback −0.5*VREF to the switched capacitor amplifier circuit 102.

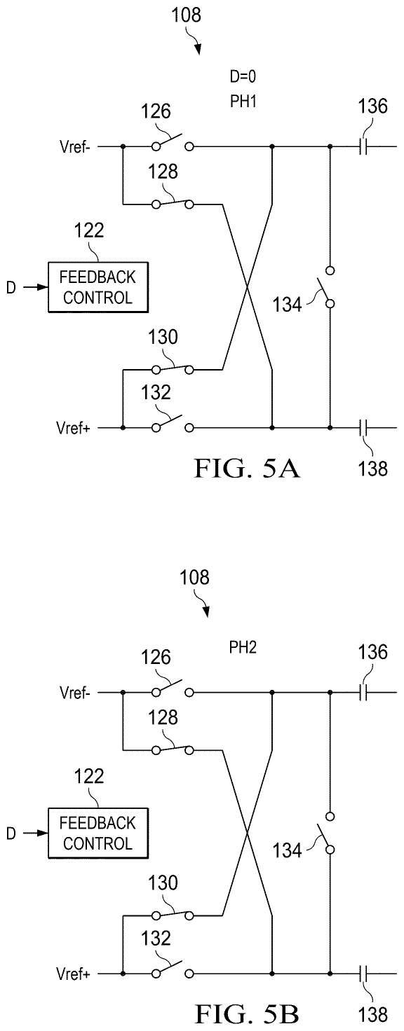

FIGS. 5A and 5B show the CDAC 108 set for phases 1 and 2 respectively with D=0. In FIG. 5A (phase 1), the feedback control circuit 122 opens the switches 126, 132, and 134, and closes the switches 128 and 130. Vref+ is coupled to the first terminal of the capacitor 136, and Vref− is coupled to the first terminal of the capacitor 138. In FIG. 4B (phase 2), the feedback control circuit 122 opens the switches 126, 132, and 134, and closes the switches 128 and 130. Vref+ is coupled to the first terminal of the capacitor 136, and Vref− is coupled to the first terminal of the capacitor 138.

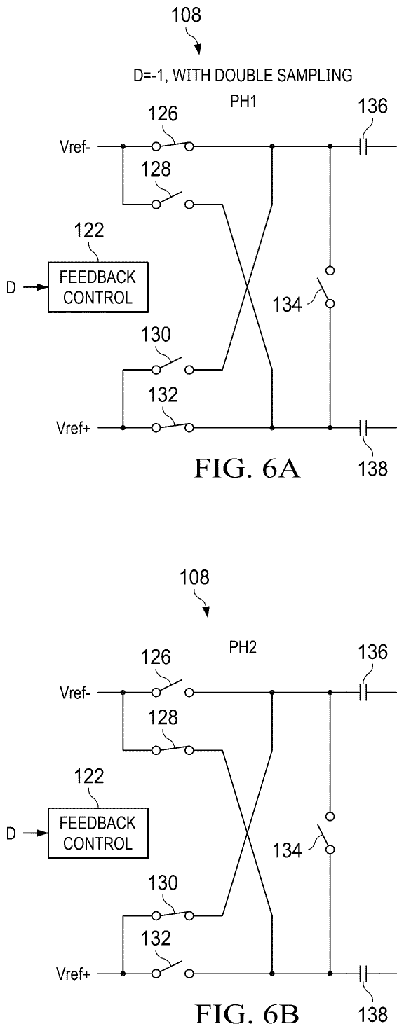

FIGS. 6A and 6B show the CDAC 108 set for phases 1 and 2 respectively with D=−1. In FIG. 6A (phase 1), the feedback control circuit 122 opens the switches 128, 130, and 134, and closes the switches 126 and 132. Vref− is coupled to the first terminal of the capacitor 136, and Vref+ is coupled to the first terminal of the capacitor 138. In FIG. 3B (phase 2), the feedback control circuit 122 opens the switches 126, 132, and 134, and closes the switches 128 and 130. Vref− is coupled to the first terminal of the capacitor 138, and Vref+ is coupled to the first terminal of the capacitor 136. The operations of FIGS. 6A and 6B perform a double sampling of reference voltage and feedback Vref+ to the switched capacitor amplifier circuit 102.

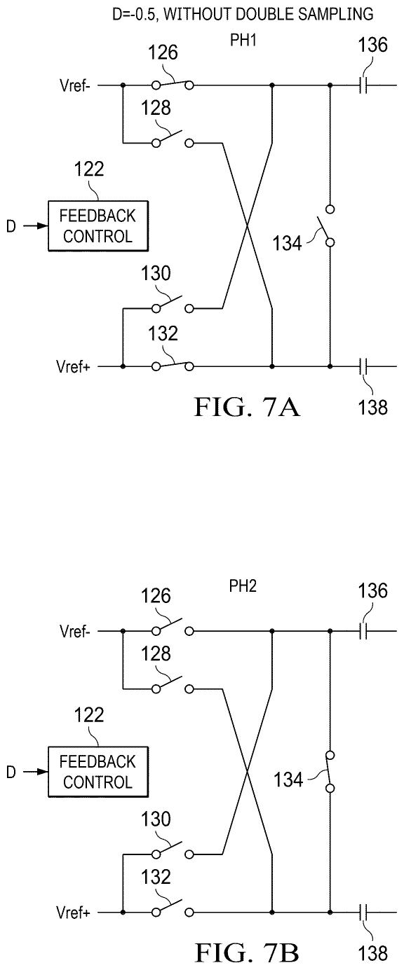

FIGS. 7A and 7B show the CDAC 108 set for phases 1 and 2 respectively with D=−0.5. In FIG. 7A (phase 1), the feedback control circuit 122 opens the switches 128, 130, and 134, and closes the switches 126 and 132. Vref+ is coupled to the first terminal of the capacitor 138, and Vref− is coupled to the first terminal of the capacitor 136. In FIG. 7B (phase 2), the feedback control circuit 122 opens the switches 126, 128, 130, and 132, and closes the switch 134. The first terminal of the capacitor 136 is coupled to the first terminal of the capacitor 138 via the switch 134. The operations of FIGS. 7A and 7B perform a single sampling of reference voltage and feedback 0.5*VREF to the switched capacitor amplifier circuit 102.

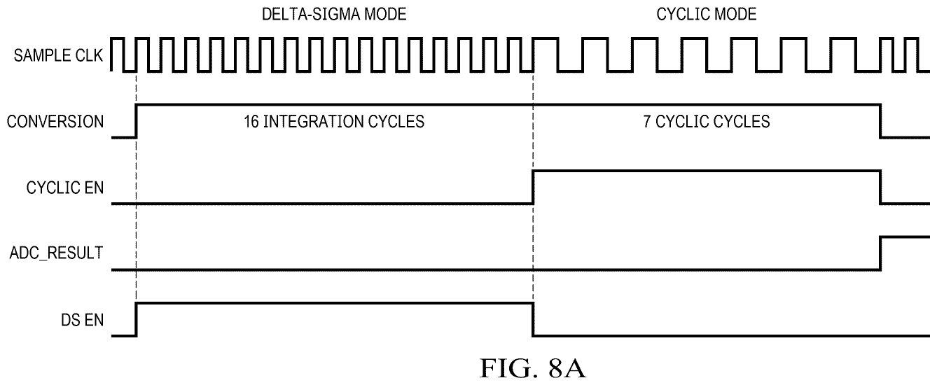

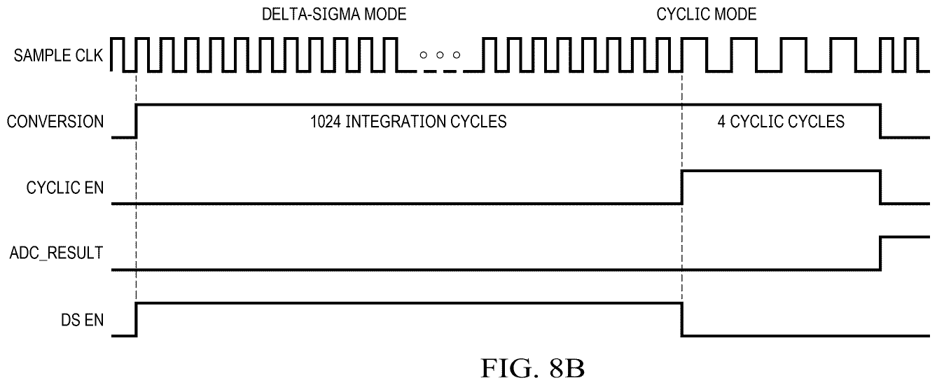

FIGS. 8A and 8B are timing diagrams showing example timing of delta-sigma and cyclic conversions in the hybrid ADC of FIG. 1. In FIG. 8A, conversion time is relatively short. The hybrid ADC 100 executes delta-sigma conversion (DS EN is logic high) in 16 cycles of SAMPLE CLK, and executes cyclic conversion (CYCLIC EN is logic high) in 7 cycles of SAMPLE CLK. The period of SAMPLE CLK may be longer in cyclic conversion than in delta-sigma conversion in some examples of the hybrid ADC 100, where a longer cycle time may provide more settling time for cyclic conversion.

In FIG. 8B, conversion time is relatively long. The hybrid ADC 100 executes delta-sigma conversion (DS EN is logic high) in 1024 cycles of SAMPLE CLK, and executes cyclic conversion (CYCLIC EN is logic high) in 4 cycles of SAMPLE CLK. The result produced by the conversion of FIG. 6B may be more accurate than the result produced by the conversion of FIG. 6B, but takes significantly (34 times) longer.

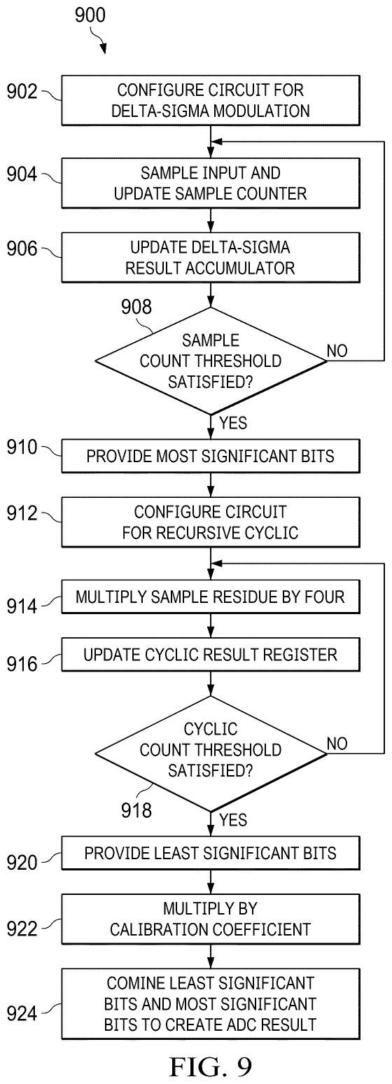

FIG. 9 is a flow diagram for an example method 900 for analog-to-digital conversion using a hybrid ADC. Though depicted sequentially as a matter of convenience, at least some of the actions shown can be performed in a different order and/or performed in parallel. Additionally, some implementations may perform only some of the actions shown. The operations of the method 900 may be performed by an example of the hybrid ADC 100.

In block 902, the hybrid ADC 100 configures the switched capacitor amplifier circuit 102 for delta-sigma conversion. Such configuration includes setting the switches of the switched capacitor amplifier circuit 102 for delta-sigma conversion as described with respect to FIG. 1.

In block 904, with the switched capacitor amplifier circuit 102 configured for delta-sigma conversion, the switched capacitor amplifier circuit 102 samples voltage at Vin+ and Vin−, and the delta-sigma cycle counter 114 is incremented.

In block 906, the multi-bit quantizer circuit 104 quantizes the output signal of the switched capacitor amplifier circuit 102 to generate multi-bit quantization value D. D is added to the delta-sigma result value stored in the accumulator register 164 to update the delta-sigma result.

In block 908, the hybrid ADC 100 determines whether a predefined number of samples have been processed (e.g., according to the delta-sigma cycle counter 114). As shown in FIGS. 8A and 8B, the number of samples processed in a delta-sigma conversion can vary to trade off accuracy for conversion time. The predefined number of samples to process in a delta-sigma conversion may be fixed at manufacture or may be user selectable in various examples of the hybrid ADC 100. If the predefined number of samples have not been processed, then delta-sigma conversion continues in block 904.

If the predefined number of samples have been processed, then in bock 910 the delta-sigma conversion result is provided to the result combination circuit 112 to serve as the most significant bits of an ADC result value.

In block 912, the hybrid ADC 100 configures the switched capacitor amplifier circuit 102 for cyclic conversion. Such configuration includes setting the switches of the switched capacitor amplifier circuit 102 for cyclic conversion as described with respect to FIG. 1.

With the switched capacitor amplifier circuit 102 configured to cyclic conversion, the switched capacitor amplifier circuit 102 multiples the sample residue left over from delta-sigma conversion by four in block 914.

In block 916, the multi-bit quantizer circuit 104 compares the multiplied sample residue to the reference voltages described with reference to FIG. 2, and the cyclic conversion result stored in the cyclic result register 110 is updated based on the results of the comparisons.

A cyclic count value is incremented and compared to a cyclic conversion cycle count threshold in block 918. For example, the conversion control circuit 174 may include a counter that counts that number of cycles of the SAMPLE CLK in a cyclic conversion, where the number of cycles in a cyclic conversion is programmable. If the cyclic count value is less than the threshold, then cyclic conversion continues in block 914.

If the cyclic count value is not less than the threshold, then the cyclic result register 110 provides the cyclic conversion result for combination with the delta-sigma conversion result in block 920.

In block 922, the calibration circuit 116 multiplies the cyclic conversion result received from the cyclic result register 110 by a calibration coefficient to produce a calibrated cyclic conversion result. In some examples of the hybrid ADC 100, the calibration coefficients may be determined by comparing two measurements made using the hybrid ADC 100. The first measurement may be low data rate measurement as shown in FIG. 8B, and the second measurement may be high data rate measurement as shown in FIG. 8A (or an average of multiple high data rate measurements).

In block 924, the result combination circuit 112 combines the delta-sigma conversion result and the calibrated cyclic conversion result to produce an ADC result value. The delta-sigma conversion result may provide the MSBs of the ADC result value, and the calibrated cyclic conversion result may provide the LSBs of the ADC result. Combining the delta-sigma conversion result and the calibrated cyclic conversion result may include appending the two results, or shifting and adding the two results.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Modifications are possible in the described embodiments, and other embodiments are possible, within the scope of the claims.

What is claimed is:

1. A circuit comprising:
a switched capacitor amplifier circuit having an output;
a multi-bit quantizer circuit having an input coupled to the output of the switched capacitor amplifier circuit, and an output;
an accumulator circuit having an input coupled to the output of the multi-bit quantizer circuit, and an output;
a cyclic result register having an input coupled to the output of the multi-bit quantizer, and an output; and
a result combination circuit having a first input coupled to the output of the accumulator circuit, a second input coupled to the output of the cyclic result register.

2. The circuit of claim 1, wherein the multi-bit quantizer circuit includes:
a first comparator having a first input coupled to a first voltage reference terminal, a second input coupled to the output of the switched capacitor amplifier circuit, and an output coupled to the output of the multi-bit quantizer;
a second comparator having a first input coupled to a second voltage reference terminal, a second input coupled to the second input of the first comparator, and an output coupled to the output of the multi-bit quantizer;
a third comparator having a first input coupled to the first voltage reference terminal, a second input coupled to the output of the switched capacitor amplifier circuit, and an output coupled to the output of the multi-bit quantizer; and
a fourth comparator having a first input coupled to a second voltage reference terminal, a second input coupled to the second input of the third comparator, and an output coupled to the output of the multi-bit quantizer.

3. The circuit of claim 1, further comprising a capacitive digital-to-analog converter (CDAC) having an input coupled to the output of the multi-bit quantizer circuit, and an output coupled to the input of the switched capacitor amplifier circuit.

4. The circuit of claim 3, wherein:
the switched capacitor amplifier circuit includes a first input and a second input; and
the CDAC includes:
a first capacitor having a first terminal coupled to the first input of the switched capacitor amplifier, and a second terminal;
a second capacitor having a first terminal coupled to the second input of the switched capacitor amplifier, and a second terminal;
a first switch coupled between the second terminal of the first capacitor and a first reference terminal;
a second switch coupled between the second terminal of the second capacitor and the first reference terminal;
a third switch coupled between the second terminal of the first capacitor and a second reference terminal;
a fourth switch coupled between the second terminal of the second capacitor and the second reference terminal; and
a fifth switch coupled between the second terminal of the first capacitor and the second terminal of the second capacitor.

5. The circuit of claim 4, wherein the CDAC includes a control circuit having an input coupled to the output of the multi-bit quantizer circuit, a first output coupled to the first switch, a second output coupled to the second switch, a third output coupled to the third switch, a fourth output coupled to the fourth switch, and a fifth output coupled to the fifth switch.

6. The circuit of claim 5, wherein the control circuit is configured to:
responsive to an output signal of the multi-bit quantizer circuit having a first value:
in a first phase, close the second switch and the third switch, and open the first switch, the fourth switch and the fifth switch; and
in a second phase, close the first switch and the fourth switch, and open the second switch, the third switch and the fifth switch;
responsive to an output signal of the multi-bit quantizer circuit having a second value:
in the first phase, close the second switch and the third switch, and open the first switch, the fourth switch and the fifth switch; and
in the second phase, close the fifth switch, and open the first switch, the second switch, the third switch and the fourth switch;
responsive to an output signal of the multi-bit quantizer circuit having a third value:
in the first phase, close the second switch and the third switch, and open the first switch, the fourth switch and the fifth switch; and
in the second phase, close the second switch and the third switch, and open the first switch, the fourth switch and the fifth switch.

7. The circuit of claim 1, wherein the result combination circuit is configured to combine a delta-sigma conversion result received at the first input and a cyclic conversion result received at the second input to produce an ADC result.

8. The circuit of claim 1, wherein the accumulator circuit is configured to:
sum a multi-bit value received at the input of the accumulator circuit and an accumulated value stored in the accumulator circuit; and
provide the accumulated value at the output of the accumulator circuit.

9. The circuit of claim 1, further comprising a calibration circuit having an input coupled to the output of the cyclic result register, and an output coupled to the second input of the result combination circuit, the calibration circuit configured to multiply a cyclic conversion result received at the input of the calibration circuit by a calibration coefficient stored in the calibration circuit to produce a calibrated cyclic conversion result provided at the output of the calibration circuit.

10. An analog-to-digital converter (ADC) comprising:
a switched capacitor amplifier having a first input, a second input, and an output;
a capacitive digital-to-analog converter (CDAC) having a first output coupled to the first input of the switched capacitor amplifier, a second output coupled to the second input of the switched capacitor amplifier, and an output;
a multi-bit quantizer circuit having an input coupled to the output of the switched capacitor amplifier, and an output coupled to the input of the CDAC;
an accumulator circuit having an input coupled to the output of the multi-bit quantizer circuit, and an output;
a cyclic result register having an input couped to the output of the multi-bit quantizer circuit, and an output;
a calibration circuit having an input coupled to the output of the cyclic result register, and an output; and
a result combination circuit having a first input coupled to the output of the accumulator circuit, a second input coupled to the output of the calibration circuit.

11. The ADC of claim 10, wherein the multi-bit quantizer circuit includes:
a first comparator configured to compare a switched capacitor amplifier output signal to a first reference voltage; and
a second comparator configured to compare the switched capacitor amplifier output signal to a second reference voltage;
a third comparator configured to compare a switched capacitor amplifier output signal to a third reference voltage; and
a fourth comparator configured to compare the switched capacitor amplifier output signal to a fourth reference voltage.

12. The ADC of claim 10, wherein the calibration circuit is configured to multiply a value received at the input of the calibration circuit by a calibration coefficient stored in the calibration circuit to produce a calibrated cyclic conversion result provided at the output of the calibration circuit.

13. The ADC of claim 10, wherein the accumulator circuit is configured to:
sum a multi-bit value received at the input of the accumulator circuit and an accumulated value stored in the accumulator circuit; and
provide the accumulated value at the output of the accumulator circuit.

14. The ADC of claim 10, wherein the CDAC is configured to operate in a double sampling mode responsive to a multi-bit value received at the input of the CDAC having a first value, and operate in a single sampling mode responsive to the multi-bit value having a second value.

15. A circuit comprising:
a switched capacitor amplifier circuit configured for delta-sigma analog-to-digital conversion and cyclic analog-to-digital conversion;
a multi-bit quantizer circuit coupled to the switched capacitor amplifier circuit, the multi-bit quantizer circuit configured to quantize an output signal of the switch capacitor amplifier circuit to multiple bits;
an accumulator circuit coupled to the multi-bit quantizer circuit, the accumulator circuit configured to accumulate the multiple bits into a delta-sigma conversion result;
a cyclic result register coupled to the multi-bit quantizer circuit, the cyclic result register configured to store the multiple bits in a cyclic conversion result; and
a result combination circuit coupled to the accumulator circuit and the cyclic result register, the result combination circuit configured to combine the delta-sigma conversion result and the cyclic conversion result to generate a hybrid analog-to-digital conversion result.

16. The circuit of claim 15, wherein the multi-bit quantizer circuit is configured to compare the output signal of the switched capacitor amplifier circuit to a plurality of reference voltages to produce the multiple bits.

17. The circuit of claim 15, further comprising a capacitive digital-to-analog converter (CDAC) coupled to the multi-bit quantizer circuit, the CDAC configured to convert the multiple bits to an analog signal, and provide the analog signal to the switched capacitor amplifier circuit for use in the delta-sigma analog-to-digital conversion and the cyclic analog-to-digital conversion.

18. The circuit of claim 17, wherein the CDAC is configured to operate in a double sampling mode responsive to the multiple bits having a first value, and operate in a single sampling mode responsive to the multiple bits having a second value.

19. The circuit of claim 15 further comprising a calibration circuit coupled between the cyclic result register and the result combination circuit, the calibration circuit configured to multiply the cyclic conversion result by a calibration coefficient to provide a calibrated cyclic conversion result.

20. The circuit of claim 19, wherein the result combination circuit is configured to combine the calibrated cyclic conversion result and the delta-sigma conversion result to generate the hybrid analog-to-digital conversion result.
